(19) United States
(12) Patent Application Publication
(10) Pub. No.: US 2014/0168914 A1
(43) Pub. Date: Jun. 19, 2014

(54) SEMICONDUCTOR DEVICE

(71) Applicant: KABUSHIKI KAISHA TOSHIBA, Tokyo (JP)

(72) Inventors: Toshiro YOKOYAMA, Yokohama-shi (JP); Taku NISHIYAMA, Yokohama-shi (JP); Yuji SHIMODA, Yokkaichi-shi (JP); Yuuji OGAWA, Yokkaichi-shi (JP)

(73) Assignee: KABUSHIKI KAISHA TOSHIBA, Tokyo (JP)

(21) Appl. No.: 13/868,911

(22) Filed: Apr. 23, 2013

Related U.S. Application Data
(60) Provisional application No. 61/736,695, filed on Dec. 13, 2012.

(51) Int. Cl. H01L 23/58

(52) U.S. Cl. CPC H01L 23/58
USPC 361/749

(57) ABSTRACT

According to one embodiment, a semiconductor device includes a board and a semiconductor chip. The semiconductor chip includes a portion located outside the board in an extension direction of the board and a portion overlapping the board or an end face substantially aligned with an edge of the board in a thickness direction of the board.

### CROSS-REFERENCE TO RELATED APPLICATIONS

This application claims the benefit of U.S. Provisional Application No. 61/736,695, filed Dec. 13, 2012, the entire contents of which are incorporated herein by reference.

### FIELD

Embodiments described herein relate generally to semiconductor devices.

### BACKGROUND

Semiconductor devices including a board, a semiconductor chip, and electronic components are disclosed. The semiconductor chip and the electronic components are mounted on the board and located at an inner side of the outer appearance of the board.

With respect to the semiconductor device, a degree of freedom in design needs to be improved.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a cross-sectional diagram illustrating a semiconductor device according to a first embodiment;

FIG. 2 is a plan diagram illustrating an internal configuration of the semiconductor device illustrated in FIG. 1;

FIG. 3 is a plan diagram illustrating a state during manufacturing of the semiconductor device illustrated in FIG. 1;

FIG. 4 is a cross-sectional diagram of the semiconductor device taken along line F4-F4 of FIG. 2;

FIG. 5 is a plan diagram illustrating an internal configuration of a semiconductor device according to a second embodiment;

FIG. 6 is a cross-sectional diagram illustrating a semiconductor device according to a third embodiment;

FIG. 7 is a cross-sectional diagram illustrating a first modified example of the semiconductor device according to the first to third embodiments;

FIG. 8 is a cross-sectional diagram illustrating a second modified example of the semiconductor device according to the first to third embodiments;

FIG. 9 is a cross-sectional diagram illustrating a semiconductor device according to a fourth embodiment;

FIG. 10 is a cross-sectional diagram illustrating a semiconductor device according to a fifth embodiment;

FIG. 11 is a cross-sectional diagram illustrating a modified example of the semiconductor device according to the fourth and fifth embodiments;

FIG. 12 is a perspective diagram illustrating an electronic apparatus according to a sixth embodiment;

FIG. 13 is a plan diagram illustrating an inner surface of an upper cover of the electronic apparatus illustrated in FIG. 12; and

FIG. 14 is a cross-sectional diagram illustrating a state of the electronic apparatus illustrated in FIG. 12 where a semiconductor device is attached.

### DETAILED DESCRIPTION

Various embodiments will be described hereinafter with reference to the accompanying drawings.

In general, according to one embodiment, a semiconductor device comprises a board and a semiconductor chip. The semiconductor chip comprises a portion located outside the board in an extension direction of the board and a portion overlapping the board or an end face substantially aligned with an edge of the board in a thickness direction of the board.

In this specification, some components are expressed by two or more terms. Those terms are just examples. Those components may be further expressed by another or other terms. And the other components which are not expressed by two or more terms may be expressed by another or other terms.

In addition, the drawings are diagrammatically illustrated, and relationships between thickness and plane dimensions or ratios of thickness of layers may be different from real ones. Therefore, specific thickness and dimensions are determined with reference to hereinafter description. In addition, among figures in the drawings, the relationships of dimensions or the ratios may be different.

### First Embodiment

FIGS. 1 and 4 illustrate a semiconductor device 1 according to a first embodiment. The semiconductor device 1 is, for example, a semiconductor storage device, of which an example is a NAND flash memory. An example of the semiconductor device 1 is a card product such as a micro SD (trade mark) card or an SD (trade mark) card.

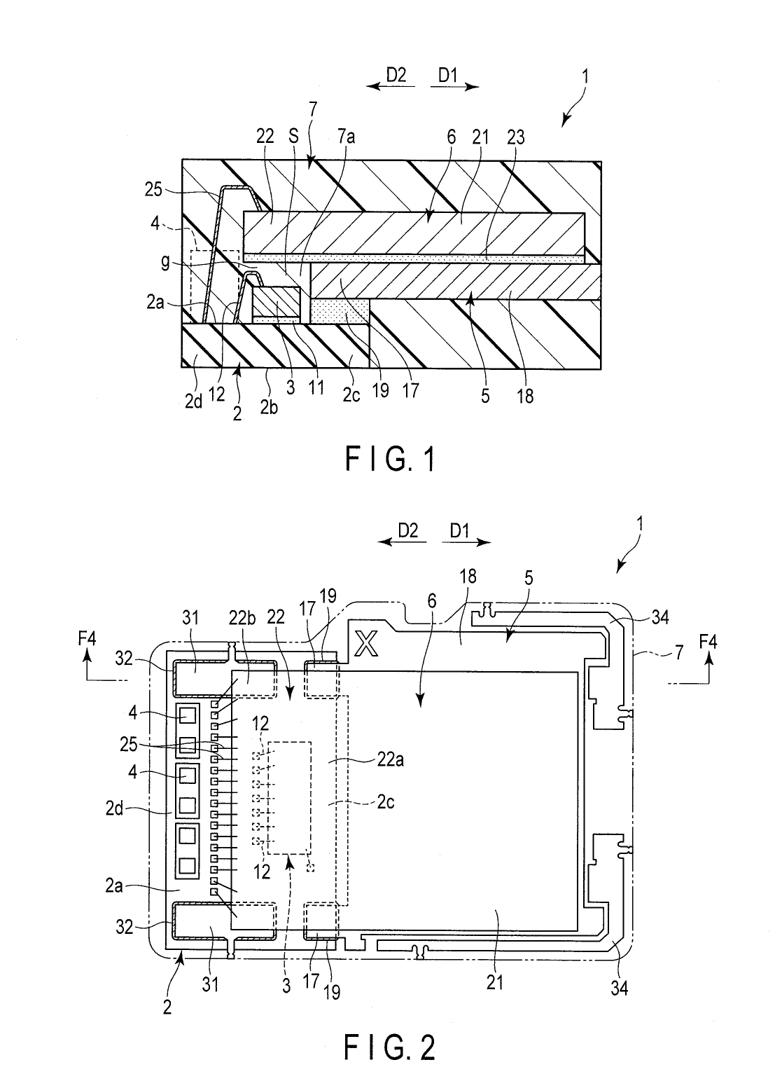

FIG. 1 is a cross-sectional diagram illustrating the semiconductor device 1. FIG. 2 is a plan diagram illustrating an internal configuration of the semiconductor device 1. In addition, in FIG. 2, for the convenience of description, adhesive portions are illustrated by hatching. As illustrated in FIGS. 1 and 2, the semiconductor device 1 includes a board 2, a controller chip 3, a passive component 4, a holder 5, a semiconductor chip 6, and a seal member 7.

The board 2 (circuit board) is configured to include a base material made of, for example, a glass epoxy resin and a wiring pattern on the base material. The board 2 has a first surface 2a (mounting surface) and a second surface 2b located at the side opposite to the first surface 2a. The first surface 2a and the second surface 2b are substantially parallel to each other and extend in the extension direction of the board 2. In other words, the first surface 2a and the second surface 2b extend in the direction intersecting the thickness direction of the board 2 (for example, the direction perpendicular to the thickness direction of the board 2).

The wire pattern is provided on the first surface 2a of the board 2. For example, an external connection terminal exposed outside the semiconductor device 1 is provided on the second surface 2b of the board 2. In addition, the board 2 has a first end 2c and a second end 2d located at the side opposite to the first end 2c.

As illustrated in FIGS. 1 and 2, the controller chip 3 is attached on the first surface 2a of the board 2. The controller chip 3 is each example of a “component”, an “electronic component”, and a “first electronic component”. As illustrated in FIG. 2, the controller chip 3 is located, for example, at a substantially central part of the board 2 in the width direction thereof.

The controller chip 3 controls operations of the semiconductor chip 6. The controller chip 3 performs writing data to the semiconductor chip 6, reading data from the semiconductor chip 6, and erasing data from the semiconductor chip 6 to manage a data storage state of the semiconductor chip 6, for example, according to external commands.

An adhesive layer 11 (first adhesive layer) is provided between the controller chip 3 and the first surface 2a of the board 2. The controller chip 3 is fixed on the first surface 2a of the board 2 by the adhesive layer 11. In addition, the controller chip 3 is electrically connected to the first surface 2a of the board 2 through bonding wires 12. A material of the bonding wire 12 is, for example, gold, but it is not limited thereto.

Similarly to the controller chip 3, the passive components 4 are mounted on the first surface 2a of the board 2. The passive component 4 is each example of a “component”, an “electronic component”, and a “second electronic component”. An example of the passive component 4 is, for example, a condenser or a resistor, but it is not limited thereto. As illustrated in FIG. 2, the passive components 4 are mounted on the second end 2d of the board 2. The passive components 4 are electrically connected to the board 2.

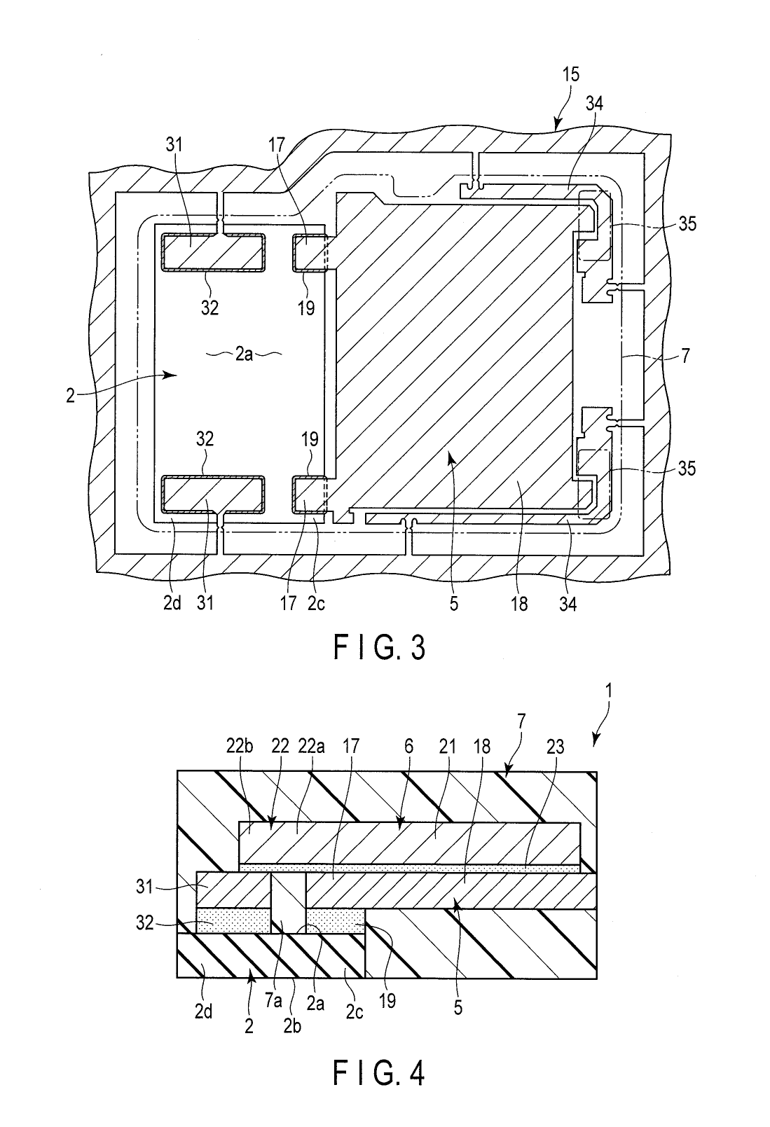

As illustrated in FIGS. 1 and 2, the holder 5 (first supporter, mounting portion, stand, frame, base) is attached to the first end 2c of the board 2 and greatly extend in the outside of the board 2. The holder 5 is formed, for example, with a portion of a metal plate 15 (see FIG. 3) called a lead frame. In addition, the holder 5 may be made of a non-metal material and may be a board made of, for example, a glass epoxy resin. As an example, the holder 5 is larger than the board 2. The holder 5 is, for example, substantially parallel to the board 2, but it is not limited thereto.

The holder 5 has, for example, a pair of first portions 17 and a second portion 18. The first portions 17 are attached on the first surface 2a of the board 2. Each of adhesive layers 19 (second adhesive layers) is provided between the each of the first portion 17 and the board 2. The first portions 17 are fixed on the first surface 2a of the board 2 by the adhesive layers 19. As illustrated in FIG. 2, a pair of the first portions 17 is provided to be divided into two ends of the holder 5 in the width direction thereof.

As illustrated in FIGS. 1 and 2, the second portion 18 of the holder 5 extends from the first portion 17 in a first direction D1. The first direction D1 is a direction oriented from the first portion 17 toward the side opposite to the central portion (or the second end 2d) of the board 2. In a different point of view, the first direction D1 is a direction which is separated from the electronic components (for example, the controller chip 3 or the passive component 4) mounted on the board 2.

The second portion 18 is located outside the board 2 in the extension direction of the board 2. In addition, in the specification, the phrase “located outside (or inside) of the board in the extension direction of the board” denotes that a portion is located at an outer side (or the inner side) of the outer appearance of the board as seen in plan view (that is, as seen in the thickness direction of the board). In other words, the second portion 18 is a portion which is protruded (projected, overhung) from the board 2 and does not overlap the board 2 in the thickness of the board 2.

As illustrated in FIGS. 1 and 2, the semiconductor chip 6 is attached to the holder 5 from the side opposite to the board 2. The semiconductor chip 6 is, for example, an arbitrary memory chip, of which an example is a NAND flash memory chip.

As illustrated in FIGS. 1 and 2, the semiconductor chip 6 has a portion which is located outside the board 2 in the extension direction of the board 2 and a portion which overlaps the board 2. In addition, in the specification, the phrase “to overlap the board” denotes that a portion overlaps the board in the thickness direction of the board (that is, a portion is located at an inner side of the outer appearance of the board as seen in plan view). In addition, the phrase “to overlap the board” also includes a state where a portion overlaps the board with a gap (space) between the portion and the board or a state where a portion overlaps the board with another member between the portion and the board.

More specifically, the semiconductor chip 6 has a first portion 21 and a second portion 22. The first portion 21 is attached to the holder 5. An adhesive layer 23 is provided between the first portion 21 and the holder 5. The first portion 21 is, for example, fixed to the holder 5 by the adhesive layer 23. The first portion 21 of the semiconductor chip 6 is, for example, spread attached to the first portion 17 and the second portion 18 of the holder 5. In other words, the first portion 21 of the semiconductor chip 6 includes a portion which overlaps the board 2 through the holder 5 interposed therebetween and a portion which is located outside the board 2 in the extension direction of the board 2.

The second portion 22 of the semiconductor chip 6 extends from the first portion 21 in a second direction D2 opposite to the first direction D1. The second direction D2 is a direction oriented from the first end 2c of the board 2 toward the controller chip 3. In a different point of view, the second direction D2 is a direction which is oriented from the first portion 21 of the semiconductor chip 6 toward the central portion of the board 2 as seen in plan view.

The second portion 22 is located outside the holder 5 in the extension direction of the board 2. In addition, in the specification, the phrase “to be located outside (or inside) of the holder in the extension direction of the board” denotes that a portion is located at an outer side (or the inner side) of the outer appearance of the holder as seen in plan view. The second portion 22 is a portion which is protruded (projected, overhung) from the holder 5 and does not overlap the holder 5 in the thickness direction of the board 2.

As illustrated in FIGS. 1 and 2, the second portion 22 of the semiconductor chip 6 faces the first surface 2a of the board 2. A space S (gap, receiving portion) is defined between the second portion 22 of the semiconductor chip 6 and the first surface 2a of the board 2.

In the embodiment, the controller chip 3 is received in the space S between the second portion 22 of the semiconductor chip 6 and the board 2. Therefore, at least a portion of the controller chip 3 is located between the second portion 22 of the semiconductor chip 6 and the board 2. The second portion 22 of the semiconductor chip 6 is overhung to the upper side (or the lower side) of the controller chip 3 to cover at least a portion of the controller chip 3. The second portion 22 of the semiconductor chip 6 faces the controller chip 3 from the side opposite to the board 2.

Herein, the second adhesive layer 19 located between the board 2 and the holder 5 is, for example, thicker than the first adhesive layer 11 located between the board 2 and the controller chip 3. In the embodiment, the sum of the thickness of the second adhesive layer 19 and the thickness of the holder 5 is larger than the sum of the thickness of the first adhesive layer 11 and the thickness of the controller chip 3. Therefore, a gap g (space) remains between the controller chip 3 and the second portion 22 of the semiconductor chip 6, so that the controller chip 3 and the semiconductor chip 6 are not in contact with each other.

As illustrated in FIGS. 1 and 2, the bonding wires 12 (first bonding wires) extend between the controller chip 3 and the board 2. The bonding wire 12 is an example of an “electrical connection member”. The bonding wires 12 extend from the controller chip 3 to the first surface 2a of the board 2 to electrically connect the controller chip 3 and the board 2. The bonding wire 12 extends, for example, through the gap g between the controller chip 3 and the semiconductor chip 6.

Similarly, bonding wires 25 (second bonding wires) extend between the semiconductor chip 6 and the board 2. The bonding wire 25 is an example of an “electrical connection member”. The bonding wires 25 extend from the second portion 22 of the semiconductor chip 6 to the first surface 2a of the board 2 to electrically connect the second portion 22 of the semiconductor chip 6 and the board 2.

As illustrated in FIGS. 1 and 2, in the embodiment, the passive components 4 are mounted in an area which is deviated from the area between the second portion 22 of the semiconductor chip 6 and the board 2. The height (thickness) of the passive component 4 according to the embodiment is larger than that of the controller chip 3. For example, the passive components 4 may be aligned along the second end 2d of the board 2. For example, the height of the passive component 4 is larger than a sum (that is, the thickness of the space S) of the thickness of the second adhesive layer 19 and the thickness of the holder 5.

As illustrated in FIGS. 2 and 4, the semiconductor device 1 according to the embodiment includes, for example, a plurality of supporters 31. The supporters 31 are provided on the first surface 2a of the board 2 to be separated from the holder 5. The supporters 31 are located between the board 2 and the second portion 22 of the semiconductor chip 6 to support the second portion 22 of the semiconductor chip 6.

More specifically, the supporters 31 are divided into two ends of the board 2 in the width direction thereof. As illustrated in FIG. 3, the supporters 31 are provided, for example, from another portion of the metal plate 15 called a lead frame. In other words, the supporters 31 are formed, for example, by cutting the same material (for example, metal plate) as that of the holder 5. Thickness of the supporter 31 is substantially equal to the thickness of the holder 5.

The second portion 22 of the semiconductor chip 6 has a first end 22a and a second end 22b. The first end 22a is adjacent to the first portion 21 of the semiconductor chip 6. The second end 22b is located at the side opposite to the first end 22a. The supporter 31 supports the second end 22b of the second portion 22 of the semiconductor chip 6.

An adhesive layer 32 is provided between the supporter 31 and the first surface 2a of the board 2. The supporter 31 is fixed on the first surface 2a of the board 2 by the adhesive layer 32. The thickness of the adhesive layer 32 is substantially equal to the thickness of the adhesive layer 19 between the holder 5 and the board 2.

In addition, as illustrated in FIG. 2, the semiconductor device 1 includes individual pieces 34 along the edge of the semiconductor device 1. As illustrated in FIG. 3, the individual pieces 34 are formed by cutting the same materials as those of the holder 5 and the supporter 31. The individual pieces 34 and the holder 5 are fixed to each other by adhesive portions 35 (fixing portions). According to the configuration, since the supporter 31 is provided, a titling of the holder 5 with respect to the board 2 is suppressed, so that the board 2 and the holder 5 can be easily maintained to be substantially parallel to each other.

As illustrated in FIGS. 1 and 2, the semiconductor device 1 includes a seal member 7 (resin portion, mold, or mold resin). An example of the seal member 7 is a resin (epoxy resin). The seal member 7 covers the board 2, the holder 5, the supporter 31, and the semiconductor chip 6. A portion 7a of the seal member 7 is located between the second portion 22 of the semiconductor chip 6 and the first surface 2a of the board 2 to bury the space S between the second portion 22 of the semiconductor chip 6 and the first surface 2a of the board 2.

According to the semiconductor device 1 having the configuration, it is possible to improve a degree of freedom in design, to reduce costs of materials, and to increase a size of the semiconductor chip 6 mounted on the semiconductor device 1 (or to decrease a size of the semiconductor device 1).

Herein, for the comparison, the case where the semiconductor chip 6 is located at an inner side of the holder 5 is considered. In this case, since the size of the semiconductor chip 6 is limited by the size of the holder 5, it may not be asserted that the degree of freedom in design is high. In addition, it is difficult to increase the size of the semiconductor chip 6 as well as to decrease the size of the semiconductor device 1.

On the other hand, in the embodiment, the semiconductor device 1 includes the board 2, the controller chip 3, the holder 5, and the semiconductor chip 6. The controller chip 3 is attached on the first surface 2a of the board 2. The holder 5 includes a first portion 21 which is attached on the first surface 2a of the board 2 and a second portion 22 which is located at an outer side of the board 2 in the extension direction of the board 2. The semiconductor chip 6 is attached to the holder 5.

In other words, in this configuration, the holder 5 is provided so that the board 2 extends, and the semiconductor chip 6 is held by the holder 5. Therefore, the semiconductor chip 6 needs not to be held by the board 2, so that it is possible to decrease the area of the board 2. The board 2 occupies the largest part of the material costs of the semiconductor device 1. Therefore, since the area of the board 2 can be decreased, it is possible to decrease the material costs of the semiconductor device 1.

Furthermore, in the embodiment, the semiconductor chip 6 includes a first portion 21 which is attached to the holder 5 and a second portion 22 which is located at an outer side of the holder 5 in an extension direction of the board 2 and faces the first surface 2a of the board 2. In other words, in the embodiment, the semiconductor chip 6 is overhung from the holder 5 by using a step difference between the board 2 and the holder 5. Therefore, a degree of arrangement of the semiconductor chip 6 is increased, the degree of freedom in design of the semiconductor device 1 is improved, and a larger semiconductor chip 6 can be mounted.

In the embodiment, a portion 7a of the seal member 7 is located between the second portion 22 of the semiconductor chip 6 and the first surface 2a of the board 2. According to the configuration, the second portion 22 of the semiconductor chip 6 is supported by the seal member 7. Therefore, it is possible to improve reliability of the semiconductor device 1. In the embodiment, the first portion 21 of the semiconductor chip 6 is attached to the first portion 17 and the second portion 18 of the holder 5. According to the configuration, it is possible to further increase a size of the semiconductor chip 6.

In the embodiment, the second portion 22 of the semiconductor chip 6 faces the controller chip 3 from the side opposite to the board 2. In other words, the component is disposed just below the overhung portion of the semiconductor chip 6. According to the configuration, since the size of the semiconductor chip 6 can be increased up to the area covering the electronic components, it is possible to further increase the size of the semiconductor chip 6.

In the embodiment, the second adhesive layer 19 between the board 2 and the holder 5 is thicker than the first adhesive layer 11 between the board 2 and the controller chip 3. According to the configuration, it is possible to easily secure the space S receiving the controller chip 3 between the board 2 and the second portion 22 of the semiconductor chip 6.

In the embodiment, the semiconductor device 1 includes a supporter 31 which is provided on the first surface 2a of the board 2 to be separated from the holder 5 and located between the board 2 and the second portion 22 of the semiconductor chip 6. According to the configuration, the second portion 22 of the semiconductor chip 6 is stably supported. For example, in the case where the bonding wire 25 is attached to the second portion 22 of the semiconductor chip 6, if the second portion 22 of the semiconductor chip 6 is supported by the supporter 31, the stability of connection of the bonding wire 25 can be improved.

In the embodiment, the second portion 22 of the semiconductor chip 6 includes a first end 22a which is adjacent to the first portion 21 of the semiconductor chip 6 and a second end 22b which is located at the side opposite to the first end 22a. The second end 22b of the second portion 22 of the semiconductor chip 6 is supported by supporter 31. According to the configuration, the second portion 22 of the semiconductor chip 6 is more stably supported.

### Second Embodiment

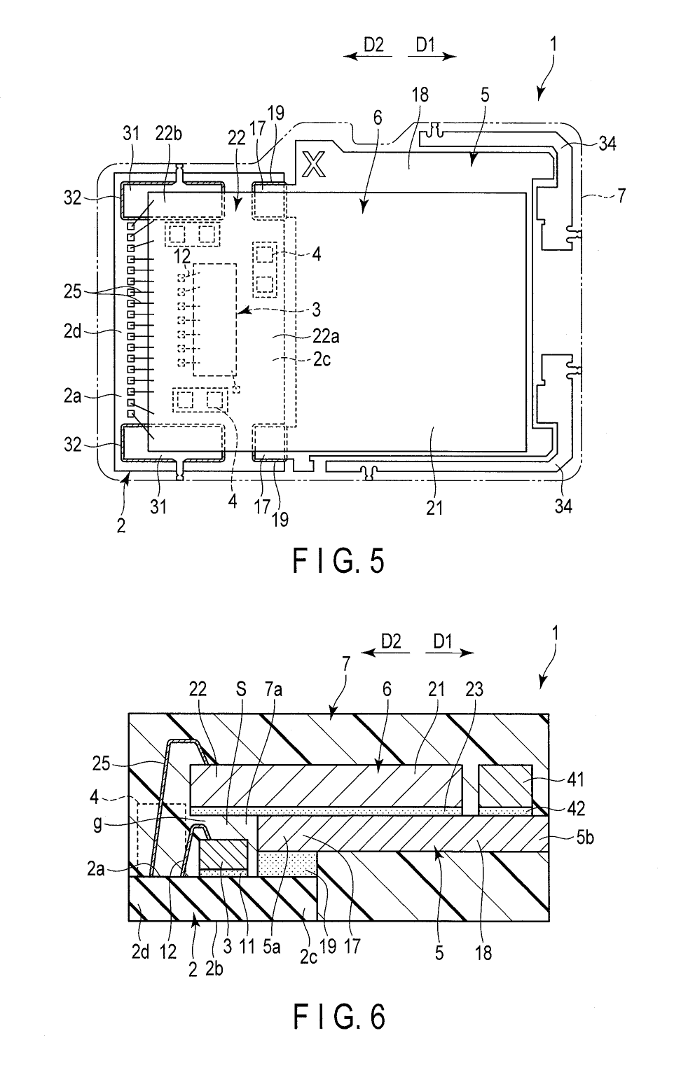

Next, a semiconductor device 1 according to a second embodiment will be described with reference to FIG. 5. In addition, the elements having functions the same as or similar to the functions of the first embodiment are denoted by the same reference numerals, and the description thereof is not presented. In addition, the elements except for the elements described below are the same as those of the first embodiment.

As illustrated in FIG. 5, in the embodiment, similarly to the controller chip 3, the passive components 4 are received in the space S between the second portion 22 of the semiconductor chip 6 and the board 2. Therefore, at least a portion of the passive component 4 is located between the second portion 22 of the semiconductor chip 6 and the board 2. The second portion 22 of the semiconductor chip 6 is overhung to the upper side (or the lower side) of the passive component 4 to cover at least a portion of the passive component 4. The second portion 22 of the semiconductor chip 6 faces the passive component 4 from the side opposite to the board 2.

According to the configuration, similarly to the first embodiment, it is possible to improve a degree of freedom in design, to reduce costs of materials, and to increase a size of the semiconductor chip 6 mounted on the semiconductor device 1 (or to decrease a size of the semiconductor device 1). For example, the size of the semiconductor chip 6 may be increased up to the size of the outer appearance of the semiconductor device 1.

### Third Embodiment

Next, a semiconductor device 1 according to a third embodiment will be described with reference to FIG. 6. In addition, the elements having functions the same as or similar to the functions of the first and second embodiments are denoted by the same reference numerals, and the description thereof is not presented. In addition, the elements except for the elements described below are the same as those of the first embodiment.

As illustrated in FIG. 6, the semiconductor device 1 according to the embodiment further includes a component 41 in addition to the elements of the first embodiment, for example. The component 41 faces the second portion 18 of the holder 5. In addition, the component 41 may be attached to the second portion 18 of the holder 5, for example, by an adhesive layer 42 or the like or may be floated from the second portion 18 of the holder 5 and supported by the seal member 7.

More specifically, the holder 5 includes a first end 5a and a second end 5b. The first end 5a is fixed to the board 2. The second end 5b is located at the side opposite to the first end 5a and is located in the end of the semiconductor device 1. The component 41 faces the second end 5b of the holder 5. The component 41 is, for example, an antenna, but it is not limited thereto.

According to the configuration, similarly to the first embodiment, it is possible to improve a degree of freedom in design, to reduce costs of materials, and to increase a size of the semiconductor chip 6 mounted on the semiconductor device 1 (or to decrease a size of the semiconductor device 1). Furthermore, according to the embodiment, since the semiconductor chip 6 is allowed to be overhung from the holder 5, the components 41 can be mounted on the holder 5, while the size of the semiconductor chip 6 is increased.

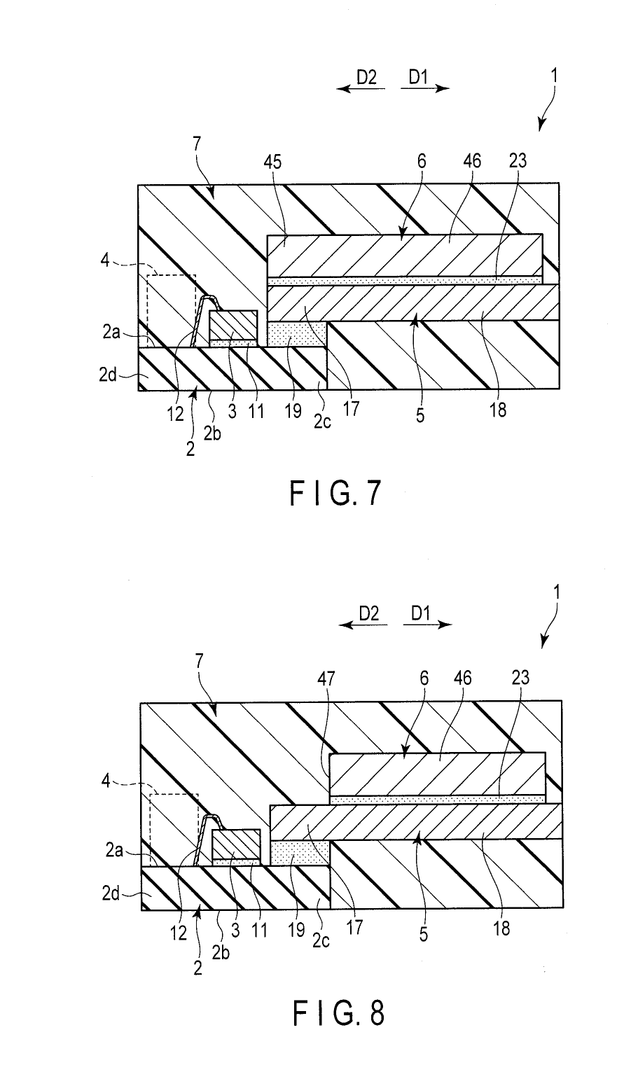

Next, modified examples of the semiconductor devices 1 according to the first to third embodiments will be described with reference to FIGS. 7 and 8.

FIG. 7 illustrates a semiconductor device 1 according to a first modified example. As illustrated in FIG. 7, the semiconductor chip 6 include a first portion 45 which overlaps the board 2 in the thickness direction of the board 2 and a second portion 46 which is located outside the board 2 in the extension direction of the board 2. The semiconductor chip 6 according to the modified example is located at an inner side of the outer appearance of the holder 5.

FIG. 8 illustrates a semiconductor device 1 according to a second modified example. As illustrated in FIG. 8, the semiconductor chip 6 includes an end face 47 which is substantially aligned with an edge of the board 2 in the thickness direction of the board 2 and a portion 46 which is located outside the board 2 in the extension direction of the board 2. The semiconductor chip 6 according to the modified example is located at an inner side of the outer appearance of the holder 5.

According to the configuration, it is possible to improve a degree of freedom in design, to reduce costs of materials, and to increase a size of the semiconductor chip 6 mounted on the semiconductor device 1 (or to decrease a size of the semiconductor device 1).

### Fourth Embodiment

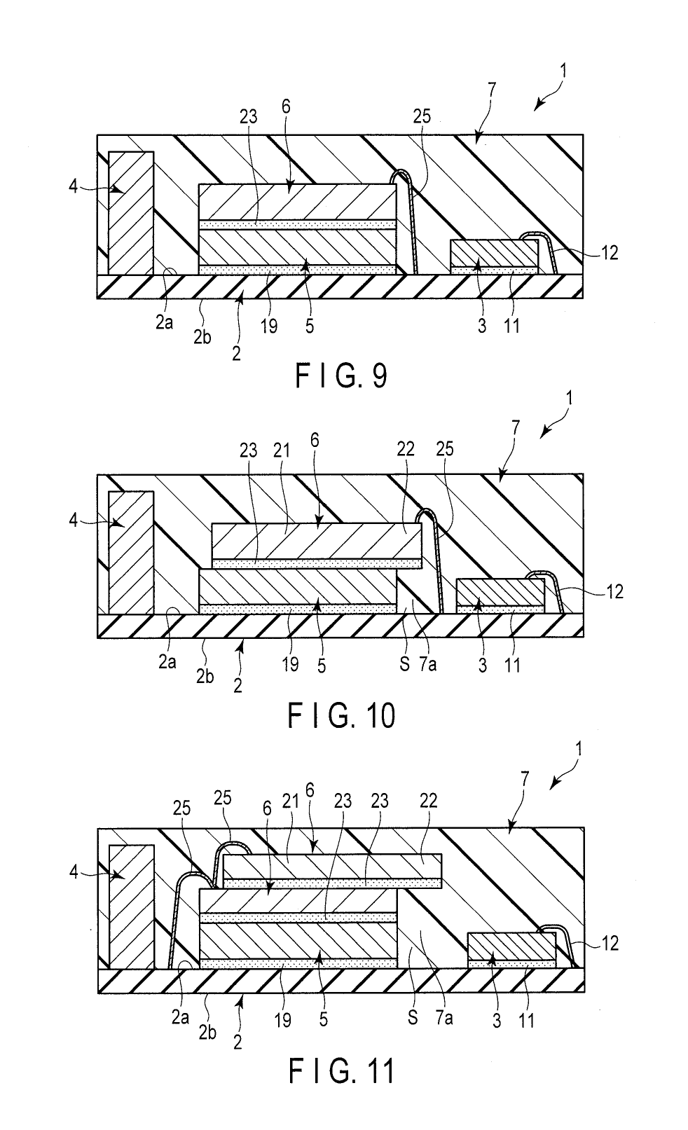

Next, a semiconductor device 1 according to a fourth embodiment will be described with reference to FIG. 9. In addition, the elements having functions the same as or similar to the functions of the first to third embodiments are denoted by the same reference numerals, and the description thereof is not presented. In addition, the elements except for the elements described below are the same as those of the first embodiment.

As illustrated in FIG. 9, the semiconductor device 1 according to the embodiment is configured to include a board 2, a controller chip 3, a holder 5, a semiconductor chip 6, and a passive component 4. For example, the size of the board 2 is substantially equal to the size of the outer appearance of the semiconductor device 1. The controller chip 3 is attached on a first surface 2a of the board 2.

The holder 5 is attached on the first surface 2a of the board 2. In the embodiment, the holder 5 is, for example, a dummy component (dummy chip). In other words, an example of the holder 5 is an electronic component which is mounted on the board 2 and is not electrically connected to the controller chip 3. In addition, a material of the dummy component is not particularly limited. In the embodiment, the semiconductor chip 6 is attached on the holder 5 which is formed as a dummy component.

The passive component 4 is provided in an area which is deviated from the holder 5 and the semiconductor chip 6. For example, the height of the passive component 4 is larger than a sum of the thickness of the holder 5 and the thickness of the semiconductor chip 6. In other words, for example, the height of the passive component 4 is larger than a sum of the thickness of the holder 5, the thickness of the adhesive layer 19, the thickness of the semiconductor chip 6, and the thickness of the adhesive layer 23.

According to the configuration, it is possible to improve a degree of freedom in design of the semiconductor device 1.

Herein, for the comparison, the case where the holder 5 does not exist and the semiconductor chip 6 is attached to the board 2 is considered. In the case where the seal member 7 is made of a thermosetting resin, in general, hardening shrinkage caused by a change in temperature in a molding process occurs in the seal member 7. Herein, if a difference between the height of the semiconductor chip 6 and the height of the passive component 4 is large, the volume of the seal member 7 is increased. If the volume of the seal member 7 is increased, stress to the semiconductor chip 6 is increased due to the hardening shrinkage, so that the semiconductor chip 6 may be damaged. In addition, bending may occurs in the semiconductor device 1 (bending may occurs in the package) based on a difference between the shrinkage rate of the board 2 and the shrinkage rate of the semiconductor chip 6.

As measures for solving the damage or bending caused by the hardening shrinkage, the thickness of the semiconductor chip 6 is allowed to be increased (the volume thereof is allowed to be increased), so that the stress from the seal member 7 can be decreased. However, in this case, since there is a need in the thickness of the semiconductor chip 6, a thin semiconductor chip cannot be mounted. In addition, in the case where a thin semiconductor chip is mounted, measures for decreasing the thickness of the semiconductor device 1 or increasing the thickness of the board 2 are needed. These measures may cause difficulty in using molds or a board in common.

On the other hand, according to the embodiment, the semiconductor chip 6 is mounted on the holder 5. Therefore, even if a thin semiconductor chip 6 is mounted, the volume of the seal member 7 is not easily increased. Accordingly, the influence of the hardening shrinkage can be reduced, so that it is possible to suppress the damage to the semiconductor chip 6 and the bending of the semiconductor device 1.

In other words, for example, if the holder 5 is formed with a dummy component, a thin semiconductor chip 6 can be mounted irrespective of the thickness of the semiconductor device 1. As a result, the degree of freedom in design of the semiconductor device 1 can be improved. In addition, according to the configuration of the embodiment, even in the case where a thin semiconductor chip 6 is employed, molds or the board may be used in common.

### Fifth Embodiment

Next, a semiconductor device 1 according to a fifth embodiment will be described with reference to FIG. 10. In addition, the elements having functions the same as or similar to the functions of the first to fourth embodiments are denoted by the same reference numerals, and the description thereof is not presented. In addition, the elements except for the elements described below are the same as those of the fourth embodiment.

As illustrated in FIG. 10, the semiconductor chip 6 according to the embodiment includes a first portion 21 which is attached on the holder 5 and a second portion 22 which is located outside the holder 5 in the extension direction of the board 2 and faces the first surface 2a of the board 2.

According to the configuration, similarly to the first to fourth embodiments, it is possible to improve a degree of freedom in design and to increase a size of the semiconductor chip 6 mounted on the semiconductor device 1 (or to decrease a size of the semiconductor device 1).

FIG. 11 illustrates a modified example of the semiconductor device 1 according to the fourth and fifth embodiments. As illustrated in FIG. 11, in the modified example, instead of one semiconductor chip 6, a plurality of the semiconductor chips 6 are mounted on the holder 5. According to the configuration, it is possible to further implement a large capacity of the semiconductor device 1. In addition, in the fourth and fifth embodiments and the modified example thereof, similarly to the first to third embodiment, the semiconductor chip 6 may be greatly protruded from the holder 5 and face at least a portion of the controller chip 3 (electronic component) from the side opposite to the board 2.

### Sixth Embodiment

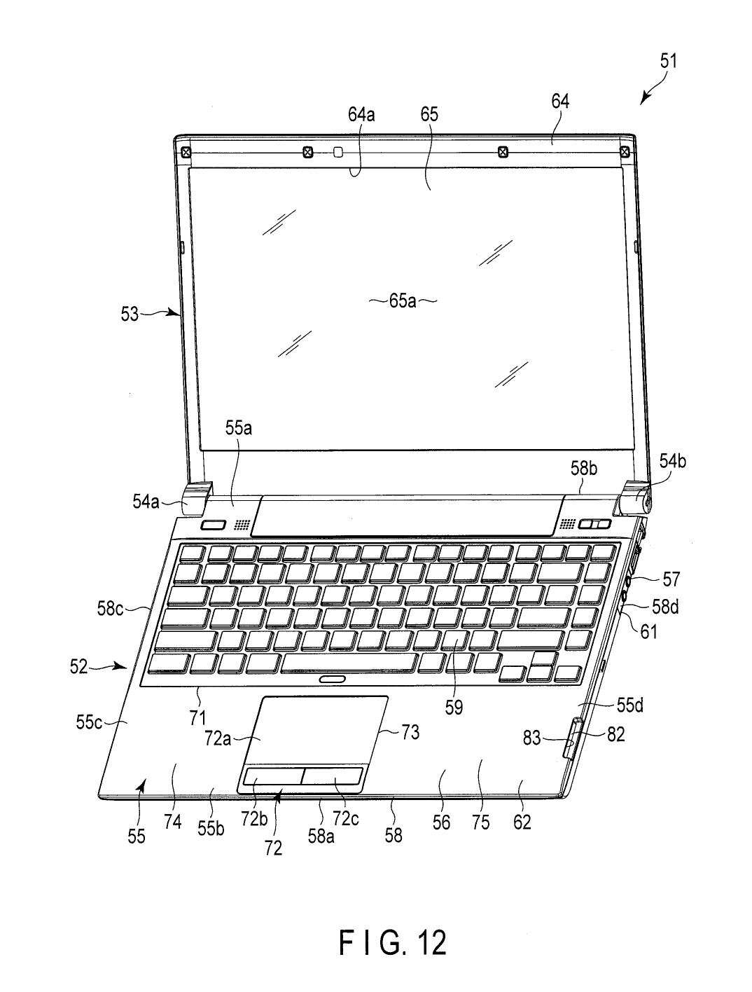

Next, an electronic apparatus 51 according to a sixth embodiment will be described with reference to FIGS. 12 to 14. In addition, the elements having functions the same as or similar to the functions of the first to fifth embodiments are denoted by the same reference numerals, and the description thereof is not presented. In addition, the elements except for the elements described below are the same as those of the third embodiment.

FIG. 12 illustrates a whole configuration of the electronic apparatus 51 according to the embodiment. For example, the electronic apparatus 51 is a notebook PC. In addition, the electronic apparatus to which the embodiment can be applied is not limited thereto. For example, the embodiment can be widely applied to various electronic apparatuses including a television set, a mobile phone (including a smart phone), and a tablet terminal.

As illustrated in FIG. 12, the electronic apparatus 51 includes a main unit 52, a display unit 53, and hinges 54a and 54b. The main unit 52 (first unit) is a main body of the electronic apparatus where a main board is mounted. The main unit 52 includes a first case 55. The first case 55 includes a top wall 56, a bottom wall 57, and a circumferential wall 58 and is formed in a flat box shape.

The bottom wall 57 faces a table surface when the electronic apparatus 51 is mounted on the table surface (external mounting surface). The bottom wall 57 is substantially parallel to the table surface. The top wall 56 spreads in substantially parallel (substantially horizontal) to the bottom wall 57 to form an empty space with respect to the bottom wall 57. A keyboard 59 is attached on the top wall 56. In addition, the keyboard 59 is an example of an “input unit”. In addition, the input unit is not limited to the keyboard, but it may be, for example, a touch panel type input unit. The circumferential wall 58 is erected with respect to the bottom wall 57 to connect the circumferential edge of the bottom wall 57 and the circumferential edge of the top wall 56.

The first case 55 includes a lower cover 61 and an upper cover 62. The lower cover 61 includes the bottom wall 57 and a part of the circumferential wall 58. The upper cover 62 includes the top wall 56 and a part of the circumferential wall 58. The upper cover 62 is assembled with the lower cover 61 to form the first case 55.

The first case 55 includes a first end 55a which is rotatably connected to the display unit 53 and a second end 55b which is located at the side opposite to the first end 55a. The circumferential wall 58 includes a front wall 58a, a rear wall 58b, a left side wall 58c, and a right side wall 58d. The front wall 58a extends in the second end 55b in the width direction (leftward/rightward direction) of the first case 55. The rear wall 58b extends in the first end 55a in the width direction of the first case 55. The left side wall 58c and the right side wall 58d extend in the depth direction (forward/backward direction) of the first case 55 to connect the ends of the front wall 58a and the ends of the rear wall 58b.

The display unit 53 (second unit) is rotatably (openably) connected to the first end 55a of the main unit 52 by the hinges 54a and 54b. The display unit 53 can be rotated between the closing position where the display unit 53 is laid down to cover main unit 52 from the upper side and the opening position where the display unit 53 is erected with respect to the main unit 52.

As illustrated in FIG. 12, the display unit 53 includes a second case 64 and a display panel 65 received in the second case 64. A display screen 65a of the display panel 65 can be exposed to an external portion through the opening portion 64a installed on the front wall of the second case 64.

As illustrated in FIG. 12, the top wall 56 includes a keyboard attachment portion 71 to which a keyboard 59 is attached, a touch pad attachment portion 73 to which a touch pad unit 72 is attached, a first palm rest 74, and a second palm rest 75. The keyboard attachment portion 71 extends to be substantially parallel to the front wall 58a and the rear wall 58b in the width direction of the first case 55 and extend between from the vicinity of the left side wall 58c to the vicinity of the right side wall 58d.

The keyboard attachment portion 71 is formed by recessing a portion of the inner side of the first case 55 with respect to the first palm rest 74 and the second palm rest 75, and the keyboard 59 is mounted by using the recessed portion. Therefore, the height of the surface (for example, key top) of the keyboard 59 attached to the keyboard attachment portion 71 is substantially equal to or slight greater than the height of the surface of the first palm rest 74 and the height of the surface of the second palm rest 75.

A touch pad unit 72 is attached to the touch pad attachment portion 73. The touch pad unit 72 includes a touch pad 72a which is a pointing device and, for example, a pair of buttons 72b and 72c. The touch pad attachment portion 73 is provided between the keyboard attachment portion 71 and the front wall 58a.

For example, similarly to the keyboard attachment portion 71, the touch pad attachment portion 73 is formed by recessing a portion of the inner side of the first case 55 with respect to the first palm rest 74 and the second palm rest 75, and the touch pad unit 72 is mounted by using the recessed portion. Therefore, the height of the surface of the touch pad unit 72 which is attached to the touch pad attachment portion 73 is substantially equal to the height of the surface of the first palm rest 74 and the height of the surface of the second palm rest 75.

In addition, instead of the above configuration, the touch pad attachment portion 73 may include an opening portion where the touch pad unit 72 disposed at an inner side of the first case 55 is exposed without recession with respect to the first palm rest 74 or the second palm rest 75. In this case, the touch pad unit 72 is attached to the touch pad attachment portion 73 from the inner side of the first case 55.

As illustrated in FIG. 12, the first case 55 includes a third end 55c which is an end of the first case 55 of the longitudinal direction (width direction) and a fourth end 55d. The third end 55c includes, for example, the left side wall 58c. The fourth end 55d includes, for example, the right side wall 58d.

User's hands are rested on the first palm rest 74 and the second palm rest 75, for example, during the manipulation of the keyboard 59. The first palm rest 74 and the second palm rest 75 are provided between the keyboard attachment portion 71 and the front wall 58a. The first palm rest 74 extends between the third end 55c and the touch pad unit 72. The second palm rest 75 extends between the fourth end 55d and the touch pad unit 72.

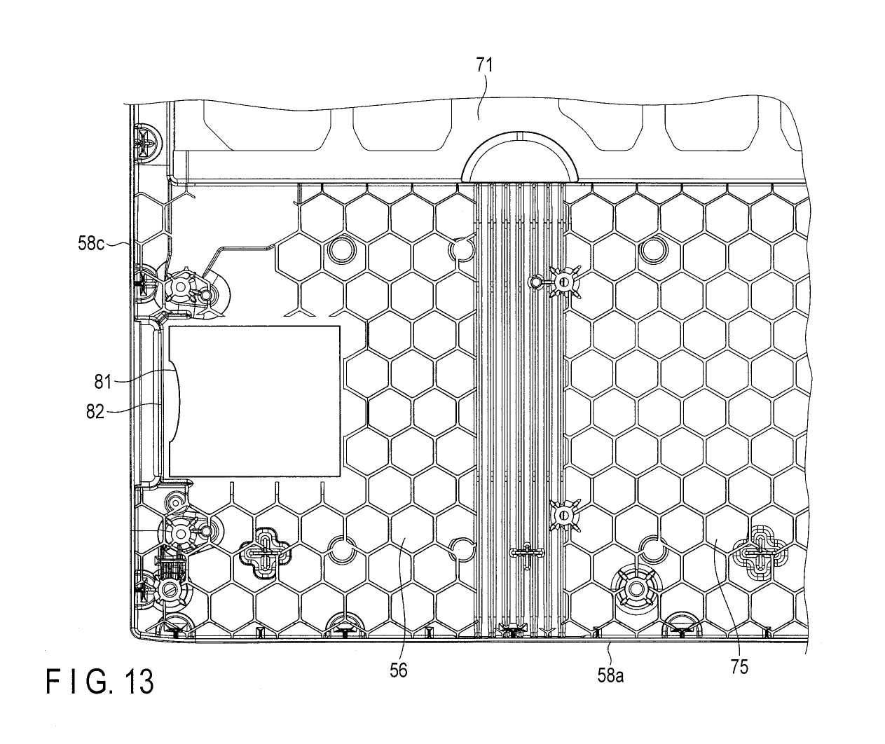

As illustrated in FIG. 13, a card slot 81 is provided in the first case 55. For example, the card slot 81 is an SD card slot, but other card slots may be used. The card slot 81 faces an inner surface of the second palm rest 75. The card slot 81 is oriented toward an opening portion 82 which is opened on the circumferential wall 58 of the first case 55. The card-type semiconductor device 1 is attached/detached through the opening portion 82 to/from the card slot 81.

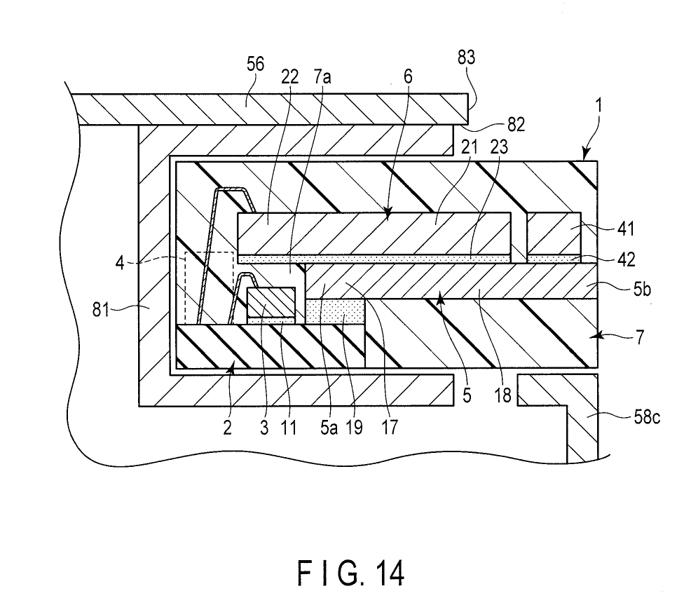

FIG. 14 illustrates a cross-sectional diagram of the electronic apparatus 51 where the semiconductor device 1 is attached to the card slot 81. As illustrated in FIGS. 12 and 14, a cutout portion 83 is formed to the corresponding to the opening portion 82 of the top wall 56. Therefore, the portion corresponding to the opening portion 82 of the top wall 56 is recessed toward an inner side of the first case 55 with respect to the right side wall 58d. Therefore, as illustrated in FIG. 14, the upper of the end of the semiconductor device 1 attached to the card slot 81 is opened. For example, in the embodiment, a conductive top wall 56 is not located on the upper of the component 41 (for example, antenna) of the semiconductor device 1. Therefore, for example, communication performance of the antenna can be improved. In addition, the semiconductor device 1 mounted on the electronic apparatus 51 is not limited to the semiconductor device 1 including the component 41. All the semiconductor devices 1 according to the first to fifth embodiments may be mounted on the electronic apparatus 51.

According to the configuration, similarly to the first to fifth embodiments, it is possible to improve a degree of freedom in design of the semiconductor device 1 and to increase a size of the semiconductor chip 6 mounted on the semiconductor device 1 (or to decrease a size of the semiconductor device 1). Furthermore, in the embodiment, in order to arrange the components 41 of the semiconductor device 1 at specific positions, the semiconductor chip 6 is allowed to be overhung from the holder 5. According to the configuration, the components 41 can be arranged at the specific position, while the size of the semiconductor chip 6 is maintained or increased. This configuration greatly contributes the improvement of a degree of freedom in design of the semiconductor device 1.

According to the first to sixth embodiments described hereinbefore, a degree of freedom in arrangement position of the semiconductor chip 6 is increased, so that it is possible to improve a degree of freedom in design of the semiconductor device 1. In addition, the configurations of the first to sixth embodiments are not limited to the aforementioned specific configurations.

For example, the material of the holder 5 and the supporter 31 are not limited to a metal, but they are boards made of a non-metal, for example, a glass epoxy resin. The semiconductor chip 6 attached to the holder 5 is not limited to one, but a plurality of the semiconductor chips 6 may be laminated.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a board comprising a first surface and a second surface at a side opposite to the first surface;
an electronic component attached on the first surface of the board;
a holder comprising a first portion attached on the first surface of the board and a second portion extending from the first portion in a first direction to be located outside the board;
a semiconductor chip which comprises a first portion attached to the holder and a second portion extending from the first portion in a second direction opposite to the first direction to be located outside the holder, the second portion of the semiconductor facing the electronic component from a side opposite to the board;
a bonding wire extending between the semiconductor chip and the board; and
a seal member covering the board, the holder, and the semiconductor chip.

2. The device of claim 1, wherein the bonding wire extends between the second portion of the semiconductor chip and the board.

3. The device of claim 1, wherein the seal member comprises a portion located between the second portion of the semiconductor chip and the first surface of the board.

4. The device of claim 1, further comprising:
a first adhesive layer located between the board and the electronic component; and
a second adhesive layer located between the board and the first portion of the holder,
wherein the second adhesive layer is thicker than the first adhesive layer.

5. The device of claim 1, further comprising a supporter separated from the holder and located between the first surface of the board and the second portion of the semiconductor chip,
wherein the second portion of the semiconductor chip comprises a first end adjacent to the first portion of the semiconductor chip and a second end at a side opposite to the first end, and
the supporter supports the second end of the second portion of the semiconductor chip.

6. A semiconductor device comprising:
a board comprising a first surface and a second surface at a side opposite to the first surface;
an electronic component attached on the first surface of the board;
a holder comprising a first portion attached on the first surface of the board;
a semiconductor chip comprising a first portion attached to the holder and a second portion located outside the holder in an extension direction of the board, the second portion facing the first surface of the board; and
a seal member covering the board, the holder, and the semiconductor chip.

7. The device of claim 6, wherein the holder comprises a second portion located outside the board in an extension direction of the board.

8. The device of claim 7, wherein the first portion of the semiconductor chip is attached to the first portion and the second portion of the holder.

9. The device of claim 6, wherein the seal member comprises a portion located between the second portion of the semiconductor chip and the first surface of the board.

10. The device of claim 6, further comprising an electrical connection member extending between the second portion of the semiconductor chip and the board.

11. A semiconductor device comprising:
a board; and
a semiconductor chip comprising a portion located outside the board in an extension direction of the board and a portion overlapping the board or an end face substantially aligned with an edge of the board in a thickness direction of the board.
